(19) United States
(12) Patent Application Publication
(10) Pub. No.: US 2026/0182030 A1
(43) Pub. Date: Jun. 25, 2026

(54) PIXEL STRUCTURE

(71) Applicant: AUO Corporation, Hsinchu City (TW)

(72) Inventor: Cheng-Wei Jiang, Hsinchu City (TW)

(73) Assignee: AUO Corporation, Hsinchu City (TW)

(21) Appl. No.: 19/295,715

(22) Filed: Aug. 11, 2025

(30) Foreign Application Priority Data
Dec. 24, 2024 (TW) 113150300

(51) Int. Cl. H10D 86/40; G09G 3/32; H10D 86/60; H10H 29/32; H10H 29/49

(52) U.S. Cl. CPC H10D 86/441; G09G 3/32; H10D 86/421; H10D 86/481; H10D 86/60; H10H 29/32; H10H 29/49

(57) ABSTRACT

A pixel structure includes a first control component group, a second control component group, a conductive structure, a first dielectric layer and a pixel element. The pixel element is electrically connected to the conductive structure, the first control component group and the second control component group. The first control component group includes a first thin film transistor. The first dielectric layer is disposed on and covers the substrate, the first control component group and the conductive structure. The second control element group includes a second thin film transistor. A normal projection area of at least one portion of the conductive structure on a substrate is greater than or substantially equal to a normal projection area of a second silicon-containing semiconductor layer of the second thin film transistor on the substrate. In addition, another pixel structure is also provided.

### CROSS-REFERENCE TO RELATED APPLICATION

This application claims the priority benefit of TW application serial no. 113150300, filed on Dec. 24, 2024. The entirety of the above-mentioned patent application is hereby incorporated by reference herein and made a part of this specification.

### BACKGROUND

### Technical Field

The present disclosure relates to a pixel structure.

### Related Art

Light emitting diode display panels include an active device substrate and a plurality of light emitting diode devices disposed on the active device substrate. Inheriting the characteristics of light emitting diodes, light emitting diode display panels have advantages such as power saving, high efficiency, high brightness, and fast response time. In addition, compared to organic light emitting diode display panels, light emitting diode display panels also have advantages such as easy color adjustment, long light emitting life, and no image burn-in. Therefore, light emitting diode display panels are regarded as the next generation display technology. Generally speaking, the pixel driving circuit of a light emitting diode display panel includes thin film transistors for providing high current. The semiconductor layer of a thin film transistor capable of providing high current may be disposed above a thicker conductive layer, and disconnection problems may easily occur.

### SUMMARY

The present disclosure provides a pixel structure that may improve disconnection problems.

The present disclosure provides another pixel structure that may improve disconnection problems.

A pixel structure according to an embodiment of the present disclosure is disposed on a substrate and includes a first control component group, a second control component group, a conductive structure, a first dielectric layer, and a pixel element. The pixel element is electrically connected to the conductive structure, the first control component group, and the second control component group. The first control component group includes at least one first thin film transistor. The first thin film transistor has a portion of a first silicon-containing semiconductor layer, a portion of a first conductive layer corresponding to the portion of the first silicon-containing semiconductor layer, a first gate dielectric layer disposed between the first silicon-containing semiconductor layer and the first conductive layer, a first source connected to the portion of the first silicon-containing semiconductor layer, and a first drain connected to the portion of the first silicon-containing semiconductor layer. The portion of the first conductive layer includes a first gate. The first dielectric layer is disposed and covers the substrate, the first control component group, and the conductive structure. The second control component group includes at least one second thin film transistor. The second thin film transistor has a second silicon-containing semiconductor layer, a second conductive layer disposed on the second silicon-containing semiconductor layer, a second gate dielectric layer disposed between the second silicon-containing semiconductor layer and the second conductive layer, a second source connected to the second silicon-containing semiconductor layer, and a second drain connected to the second silicon-containing semiconductor layer. The second conductive layer includes a second gate. The second thin film transistor is located on the conductive structure. A vertical projection area of at least a portion of the conductive structure on the substrate is greater than or substantially equal to a vertical projection area of the second silicon-containing semiconductor layer on the substrate.

A pixel structure according to another embodiment of the present disclosure is disposed on a substrate and includes a first control component group, a second control component group, a first dielectric layer, a second dielectric layer, a third dielectric layer, two junction segments, and a pixel element. The pixel element is electrically connected to the first control component group and the second control component group. The first control component group includes at least one first thin film transistor. The first thin film transistor has a first silicon-containing semiconductor layer, a second silicon-containing semiconductor layer, a first conductive layer, a second conductive layer, a first source, a first drain, a second source, and a second drain. The first conductive layer is located on the first silicon-containing semiconductor layer. The first dielectric layer covers the first silicon-containing semiconductor layer and is sandwiched between the first conductive layer and the first silicon-containing semiconductor layer. The second dielectric layer is disposed and covers the first conductive layer, the first silicon-containing semiconductor layer, and the first dielectric layer. The second silicon-containing semiconductor layer is disposed on the second dielectric layer. The second conductive layer is disposed on the second silicon-containing semiconductor layer. The third dielectric layer covers the second silicon-containing semiconductor layer and is sandwiched between the second conductive layer and the second silicon-containing semiconductor layer. The first source and the second source respectively pass through at least one of the first dielectric layer and the second dielectric layer and are connected to each other via one of the plurality of junction segments. The first drain and the second drain respectively pass through at least one of the first dielectric layer and the second dielectric layer and are connected to each other via another one of the plurality of junction segments. A vertical projection area of the second silicon-containing semiconductor layer on the substrate is smaller than or substantially equal to a vertical projection area of the first conductive layer on the substrate. The first conductive layer includes a first gate. The second conductive layer includes a second gate.

### BRIEF DESCRIPTION OF THE DRAWINGS

FIG. 1 is a schematic diagram of an equivalent circuit of a pixel structure 10 according to an embodiment of the present disclosure.

FIG. 2 is a schematic cross-sectional view of a pixel structure 10 according to an embodiment of the present disclosure.

FIG. 3 is a schematic diagram of an equivalent circuit of a pixel structure 10A according to another embodiment of the present disclosure.

FIG. 4 is a schematic cross-sectional view of a pixel structure 10A according to an embodiment of the present disclosure.

FIG. 5 is a schematic diagram of an equivalent circuit of a pixel structure 10B according to yet another embodiment of the present disclosure.

FIG. 6 is a top view and perspective schematic diagram of a first thin film transistor TAB of a pixel structure 10B according to yet another embodiment of the present disclosure.

FIG. 7 is a schematic cross-sectional view of a first thin film transistor TAB of a pixel structure 10B according to yet another embodiment of the present disclosure.

FIG. 8 is a top view and perspective schematic diagram of a first thin film transistor TAC of a pixel structure 10C according to yet another embodiment of the present disclosure.

FIG. 9 is a schematic cross-sectional view of a first thin film transistor TAC of a pixel structure 10C according to yet another embodiment of the present disclosure.

FIG. 10 is a schematic diagram of an equivalent circuit of a pixel structure 10D according to still another embodiment of the present disclosure.

FIG. 11 is a top view and perspective schematic diagram of a first thin film transistor TAD of a pixel structure 10D according to still another embodiment of the present disclosure.

FIG. 12 is a schematic cross-sectional view of a first thin film transistor TAD of a pixel structure 10D according to still another embodiment of the present disclosure.

FIG. 13 is a schematic cross-sectional view of a first thin film transistor TAD of a pixel structure 10D according to still another embodiment of the present disclosure.

FIG. 14 is a schematic cross-sectional view of a first thin film transistor TAD of a pixel structure 10D according to still another embodiment of the present disclosure.

FIG. 15 is a schematic cross-sectional view of a first thin film transistor TAD and a second thin film transistor TB of a pixel structure 10D according to still another embodiment of the present disclosure.

FIG. 16 is a top view and perspective schematic diagram of a first thin film transistor TAE of a pixel structure 10E according to an embodiment of the present disclosure.

FIG. 17 is a schematic cross-sectional view of a first thin film transistor TAE of a pixel structure 10E according to an embodiment of the present disclosure.

FIG. 18 is a schematic cross-sectional view of a first thin film transistor TAE of a pixel structure 10E according to still another embodiment of the present disclosure.

FIG. 19 is a schematic cross-sectional view of a first thin film transistor TAE of a pixel structure 10E according to still another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

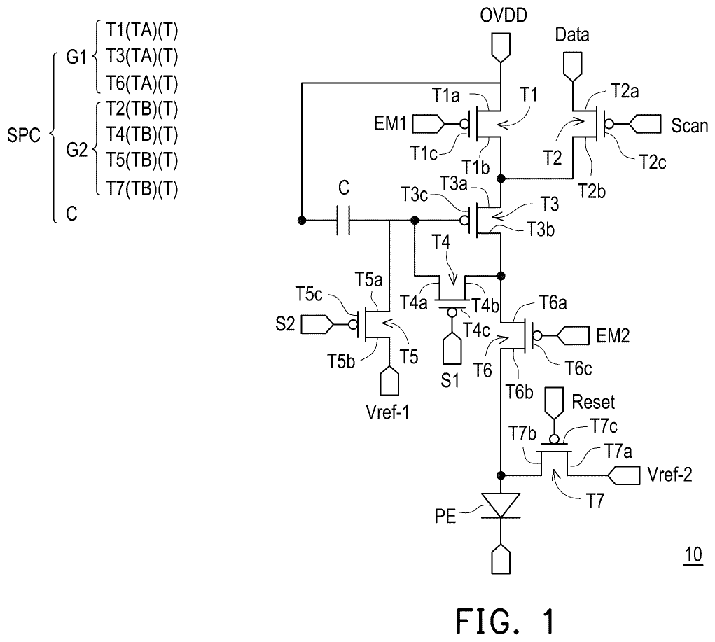

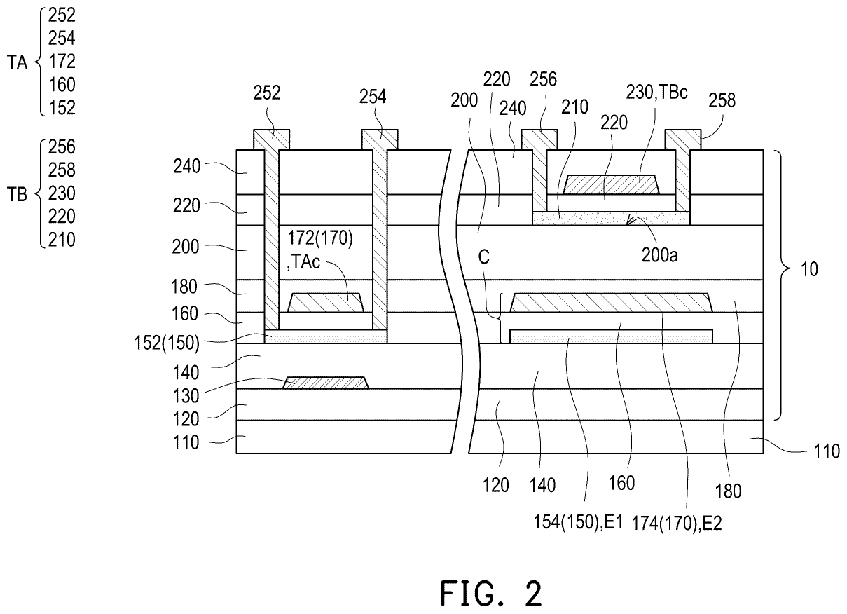

FIG. 1 is a schematic equivalent circuit diagram of a pixel structure 10 according to an embodiment of the present disclosure. FIG. 2 is a schematic cross-sectional view of a pixel structure 10 according to an embodiment of the present disclosure. Referring to FIG. 1 and FIG. 2, the pixel structure 10 is disposed on a substrate 110. In some embodiments, the material of the substrate 110 may be glass, quartz, organic polymer, or opaque/reflective material (for example:
conductive material, wafer, ceramic, or other applicable materials), or other applicable materials, but the present disclosure is not limited thereto.

Referring to FIG. 1, the pixel structure 10 includes a pixel driving circuit SPC and a pixel element PE electrically connected to the pixel driving circuit SPC. In some embodiments, the pixel element PE may be an inorganic self-luminous element, an organic self-luminous element, a non-self-luminous element, or other suitable pixel elements. In some embodiments, preferably, the pixel element PE is an inorganic self-luminous element, such as but not limited to: micro light-emitting diode (μLED).

Referring to FIG. 1, the pixel driving circuit SPC includes a first control component group G1, a second control component group G2, and at least one conductive structure C, wherein the pixel element PE is electrically connected to the conductive structure C, the first control component group G1, and the second control component group G2. In some embodiments, the pixel driving circuit SPC may include n thin film transistors T and m conductive structures C, wherein n is a positive integer greater than or equal to 2, and m is a positive integer greater than or equal to 1. In some embodiments, n may not be equal to m. For example, in some embodiments, n=7, m=1, that is, the pixel driving circuit SPC may include 7 thin film transistors T and 1 conductive structure C. In some embodiments, the conductive structure C is, for example, a capacitor structure. In brief, in some embodiments, the pixel driving circuit SPC may be a 7T1C architecture. However, the present disclosure is not limited thereto. In other embodiments, the pixel driving circuit SPC may also be other architectures, such as but not limited to: 3T1C, 4T1C, 5T1C, 6T1C, 4T2C, 5T2C, 6T2C, 7T2C, etc. It should be noted that the present disclosure does not limit the conductive structure C to necessarily be a capacitor structure. In other embodiments, the conductive structure C may also be a signal line or other type of an element.

Referring to FIG. 1, the first control component group G1 of the pixel driving circuit SPC includes at least one first thin film transistor TA. In some embodiments, the first thin film transistor TA has a higher current flow. The first control component group G1 including the first thin film transistor TA may be called a high current control component group. In some embodiments, the first thin film transistor TA of the first control component group G1 may include a driving device or a light emission control device. In some embodiments, the first thin film transistor TA is electrically connected to the pixel element PE, and the first thin film transistor TA electrically connected to the pixel element PE may be called a driving device, a light emission control device, or other devices.

Taking the 7T1C architecture as an example, the pixel driving circuit SPC may include seven thin film transistors T1, T2, T3, T4, T5, T6, T7 and one conductive structure C, wherein the source T1a of the thin film transistor T1 is electrically connected to the power terminal OVDD, the gate T1c of the thin film transistor T1 is electrically connected to the light emitting signal terminal EM1, the drain T1b of the thin film transistor T1 is electrically connected to the source T3a of the thin film transistor T3 and the drain T2b of the thin film transistor T2, the source T2a of the thin film transistor T2 is electrically connected to a data line Data, the gate T2c of the thin film transistor T2 is electrically connected to a scan line Scan, the gate T3c of the thin film transistor T3 is electrically connected to the source T4a of the thin film transistor T4, the source T4a of the thin film transistor T5 and the conductive structure C, the drain T3b of the thin film transistor T3 is electrically connected to the drain T4b of the thin film transistor T4 and the source T6a of the thin film transistor T6, the gate T4c of the thin film transistor T4 is electrically connected to the signal terminal S1, the gate T5c of the thin film transistor T5 is electrically connected to the signal terminal S2, the drain T5b of the thin film transistor T5 is electrically connected to the reference potential Vref-1, the gate T6c of the thin film transistor T6 is electrically connected to the light emitting signal terminal EM2, the drain T6b of the thin film transistor T6 is electrically connected to the pixel element PE, the source T7a of the thin film transistor T7 is electrically connected to the reference potential Vref-2, the gate T7c of the thin film transistor T7 is electrically connected to the reset signal terminal Reset, the drain T7b of the thin film transistor T7 is electrically connected to the pixel element PE, and the first thin film transistor TA may be the thin film transistor T1 (i.e., a light emission control device), the thin film transistor T3 (i.e., a driving device) or the thin film transistor T6 (i.e., a light emission control device), but the present disclosure is not limited thereto. Other details of the 7T1C architecture may refer to US Patent U.S. Pat. No. 9,343,014B2.

The second control component group G2 of the pixel driving circuit SPC includes at least one second thin film transistor TB. In some embodiments, the current flowing through the second thin film transistor TB of the second control component group G2 is of normal magnitude or lower. The second control component group G2 including the second thin film transistor TB may be called a normal current control component group or a low current control component group. For example, in the 7T1C architecture, the second thin film transistor TB may be the thin film transistor T2, the thin film transistor T4, the thin film transistor T5 or the thin film transistor T7, but the present disclosure is not limited thereto.

Referring to FIG. 2, the first thin film transistor TA has a portion 152 of the first silicon-containing semiconductor layer 150, a portion 172 of the first conductive layer 170 corresponding to the portion 152 of the first silicon-containing semiconductor layer 150, a first gate dielectric layer 160 disposed between the first silicon-containing semiconductor layer 150 and the first conductive layer 170, a first source 252 connected to the portion 152 of the first silicon-containing semiconductor layer 150, and a first drain 254 connected to the portion 152 of the first silicon-containing semiconductor layer 150, and the portion 172 of the first conductive layer 170 includes the first gate TAc of the first thin film transistor TA.

Referring to FIG. 1 and FIG. 2, in some embodiments, the first drain 254 of the first thin film transistor TA of the first control component group G1 is electrically connected to the pixel element PE. For example, in some embodiments, the drain T1b of the thin film transistor T1 in FIG. 1 is electrically connected to the pixel element PE, and the first source 252, the first drain 254, and the first gate TAc of the first thin film transistor TA in FIG. 2 may respectively refer to the source T1a, the drain T1b, and the gate T1c of the thin film transistor T1 in FIG. 1. In some embodiments, the drain T3b of the thin film transistor T3 in FIG. 1 is electrically connected to the pixel element PE, and the first source 252, the first drain 254, and the first gate TAc of the first thin film transistor TA in FIG. 2 may respectively refer to the source T3a, the drain T3b, and the gate T3c of the thin film transistor T3 in FIG. 1. In some embodiments, the drain T6b of the thin film transistor T6 in FIG. 1 is electrically connected to the pixel element PE, and the first source 252, the first drain 254, and the first gate TAc of the first thin film transistor TA in FIG. 2 may respectively refer to the source T6a, the drain T6b, and the gate T6c of the thin film transistor T6 in FIG. 1.

Referring to FIG. 2, in some embodiments, the first silicon-containing semiconductor layer 150 may have a single layer or multilayer structure. In some embodiments, the material of the first silicon-containing semiconductor layer 150 may be polycrystalline silicon, microcrystalline silicon, single crystal silicon, amorphous silicon, silicon-rich dielectric material, other suitable materials, or combinations thereof. Taking polycrystalline silicon as a preferred example, the portion 152 of the first silicon-containing semiconductor layer 150 has a channel region (not labeled) between two heavily doped regions (not labeled). In other embodiments, a lightly doped region (not labeled) may be located between the channel region and the heavily doped regions; that is, either side of the channel region may be provided with a lightly doped region and a heavily doped region. In yet another embodiment, one side of the channel region may be provided with a heavily doped region and an extension region (not labeled), while the other side of the channel region may be provided with a lightly doped region and a heavily doped region.

Referring to FIG. 2, in some embodiments, based on conductivity considerations, the first conductive layer 170, the first source 252, and/or the first drain 254 are generally made of metal material. However, the present disclosure is not limited thereto. According to other embodiments, the first conductive layer 170, the first source 252, and/or the first drain 254 may also use other conductive materials. For example: alloys, nitrides of metal materials, oxides of metal materials, oxynitrides of metal materials, or stacked layers of metal materials and other conductive materials.

Referring to FIG. 2, in some embodiments, the first gate dielectric layer 160 may have a single layer or multilayer structure. In some embodiments, the material of the first gate dielectric layer 160 may be inorganic material (for example: silicon oxide, silicon nitride, silicon oxynitride, or stacked layers of at least two of the aforementioned materials), organic material, or combinations thereof. In some embodiments, if the first gate dielectric layer 160 has a multilayer structure, and the materials of the multiple film layers of the multilayer structure may be the same or different.

Referring to FIG. 2, in some embodiments, the pixel structure 10 may further optionally include a conductive layer 130 and a buffer layer 140 disposed on the substrate 110. The conductive layer 130 is located below the portion 152 of the first silicon-containing semiconductor layer 150 of the first thin film transistor TA. The first conductive layer 170 is located above the portion 152 of the first silicon-containing semiconductor layer 150 of the first thin film transistor TA. The buffer layer 140 is sandwiched between the portion 152 of the first silicon-containing semiconductor layer 150 and the conductive layer 130. In some embodiments, the pixel structure 10 may further optionally include another buffer layer 120, wherein another buffer layer 120 is sandwiched between the conductive layer 130 and the substrate 110.

In some embodiments, based on conductivity considerations, the conductive layer 130 is generally made of metal material. However, the present disclosure is not limited thereto. According to other embodiments, the conductive layer 130 may also use other conductive materials, for example: alloys, nitrides of metal materials, oxides of metal materials, oxynitrides of metal materials, or stacked layers of metal materials and other conductive materials. In some embodiments, the buffer layer 140 and/or another buffer layer 120 may have a single layer or multilayer structure. In some embodiments, the material of the buffer layer 140 and/or another buffer layer 120 may be inorganic material (for example: silicon oxide, silicon nitride, silicon oxynitride, or stacked layers of at least two of the aforementioned materials), organic material, or combinations thereof. In some embodiments, if the buffer layer 140 and/or another buffer layer 120 have a multilayer structure, the materials of the multiple film layers of the multilayer structure may be the same or different.

Referring to FIG. 1 and FIG. 2, the pixel structure 10 further includes a first dielectric layer 200 disposed on and covering the substrate 110, the first control component group G1, and the conductive structure C. In some embodiments, the first dielectric layer 200 may have a single layer or multilayer structure. In some embodiments, the material of the first dielectric layer 200 may be inorganic material (for example: silicon oxide, silicon nitride, silicon oxynitride, or stacked layers of at least two of the aforementioned materials), organic material, or combinations thereof.

In some embodiments, the conductive structure C of FIG. 2 may be one of the conductive structures C of the pixel driving circuit SPC of FIG. 1. Referring to FIG. 2, in some embodiments, one of the multiple electrodes E1, E2 of the conductive structure C may include a portion 154 of the first silicon-containing semiconductor layer 150, another one of the multiple electrodes E1, E2 of the conductive structure C may include a portion 174 of the first conductive layer 170, the first gate dielectric layer 160 covers one of the multiple electrodes E1, E2 of the conductive structure C, and the first gate dielectric layer 160 may be sandwiched between the multiple electrodes E1, E2 of the conductive structure C, but the present disclosure is not limited thereto.

Referring to FIG. 2, in some embodiments, the pixel structure 10 may further optionally include a second dielectric layer 180 disposed between the first dielectric layer 200 and the first conductive layer 170. In some embodiments, the second dielectric layer 180 may have a single layer or multilayer structure. In some embodiments, the material of the second dielectric layer 180 may be inorganic material (for example: silicon oxide, silicon nitride, silicon oxynitride, or stacked layers of at least two of the aforementioned materials), organic material, or combinations thereof. In some embodiments, if the second dielectric layer 180 has a multilayer structure, the materials of the multiple film layers of the multilayer structure may be the same or different.

Referring to FIG. 2, the second thin film transistor TB has a second silicon-containing semiconductor layer 210, a second conductive layer 230 disposed on the second silicon-containing semiconductor layer 210, a second gate dielectric layer 220 disposed between the second silicon-containing semiconductor layer 210 and the second conductive layer 230, a second source 256 connected to the second silicon-containing semiconductor layer 210, and a second drain 258 connected to the second silicon-containing semiconductor layer 210. The second conductive layer 230 includes a second gate TBc of the second thin film transistor TB. The second thin film transistor TB is located on the conductive structure C. The first dielectric layer 200 is sandwiched between the second thin film transistor TB and the conductive structure C.

It is worth noting that a vertical projection area of at least one of the multiple electrodes E1, E2 of the conductive structure C on the substrate 110 is greater than or substantially equal to a vertical projection area of the second silicon-containing semiconductor layer 210 on the substrate 110. The vertical projection area of the second silicon-containing semiconductor layer 210 on the substrate 110 is located within the vertical projection area of at least one of the multiple electrodes E1, E2 of the conductive structure C on the substrate 110. Thereby, even if the metal layer (for example: the first conductive layer 170) below the second silicon-containing semiconductor layer 210 is thick, the second silicon-containing semiconductor layer 210 may still be formed on the flat surface 200a of the first dielectric layer 200, and disconnection problems are less likely to occur. In some embodiments, the electrode E1 may optionally belong to the first silicon-containing semiconductor layer 150 rather than belong to the metal layer, and the vertical projection area of the electrode E1 belonging to the first silicon-containing semiconductor layer 150 on the substrate 110 may optionally be greater than, equal to, or smaller than the vertical projection area of the second silicon-containing semiconductor layer 210 on the substrate 110, which is not limited by the present disclosure.

Referring to FIG. 1 and FIG. 2, in some embodiments, the second gate TBc of the second thin film transistor TB of the second control component group G2 is electrically connected to the scan line Scan, the second source 256 of the second thin film transistor TB of the second control component group G2 is electrically connected to the data line Data, and the second drain 258 of the second thin film transistor TB of the second control component group G2 is electrically connected to the first thin film transistor TA of the first control component group G1.

For example, in some embodiments, the second source 256, the second drain 258, and the second gate TBc of the second thin film transistor TB in FIG. 2 may respectively refer to the source T2a, the drain T2b, and the gate T2c of the thin film transistor T2 in FIG. 1, wherein the gate T2c of the thin film transistor T2 in FIG. 1 is electrically connected to the scan line Scan, the source T2a of the thin film transistor T2 in FIG. 1 is electrically connected to the data line Data, and the drain T2b of the thin film transistor T2 in FIG. 1 is electrically connected to the thin film transistors T1, T3.

However, the present disclosure is not limited thereto. In another embodiment, the second source 256, the second drain 258, and the second gate TBc of the second thin film transistor TB in FIG. 2 may also respectively refer to the source T4a, the drain T4b, and the gate T4c of the thin film transistor T4 in FIG. 1; in yet another embodiment, the second source 256, the second drain 258, and the second gate TBc of the second thin film transistor TB in FIG. 2 may also respectively refer to the source T5a, the drain T5b, and the gate T5c of the thin film transistor T5 in FIG. 1; in still another embodiment, the second source 256, the second drain 258, and the second gate TBc of the second thin film transistor TB in FIG. 2 may also respectively refer to the source T7a, the drain T7b, and the gate T7c of the thin film transistor T7 in FIG. 1.

Referring to FIG. 1 and FIG. 2, in some embodiments, the pixel structure 10 further includes a dielectric layer 240 disposed on the substrate 110 and covering the first control component group G1, the second control component group G2, and the conductive structure C. The first source 252 and the first drain 254 of the first thin film transistor TA penetrate through the dielectric layer 240, the first dielectric layer 200, and the first gate dielectric layer 160 and connect to a portion 152 of the first silicon-containing semiconductor layer 150. The second source 256 and the second drain 258 of the second thin film transistor TB penetrate through the dielectric layer 240 and the second gate dielectric layer 220 and connect to the second silicon-containing semiconductor layer 210. In some embodiments, the dielectric layer 240 may be a single layer or multilayer structure. In some embodiments, the material of the dielectric layer 240 may be an inorganic material (for example: silicon oxide, silicon nitride, silicon oxynitride, or a stacked layer of at least two of the aforementioned materials), an organic material, or a combination thereof. In some embodiments, if the dielectric layer 240 is a multilayer structure, the materials of the multiple film layers of the multilayer structure may be the same or different.

It must be noted that the following embodiments use the same element reference numerals and partial content as the aforementioned embodiments, wherein the same reference numerals are used to represent the same or similar elements, and descriptions of the same technical content are omitted. For descriptions of the omitted portions, reference may be made to the aforementioned embodiments, and the following embodiments will not repeat them.

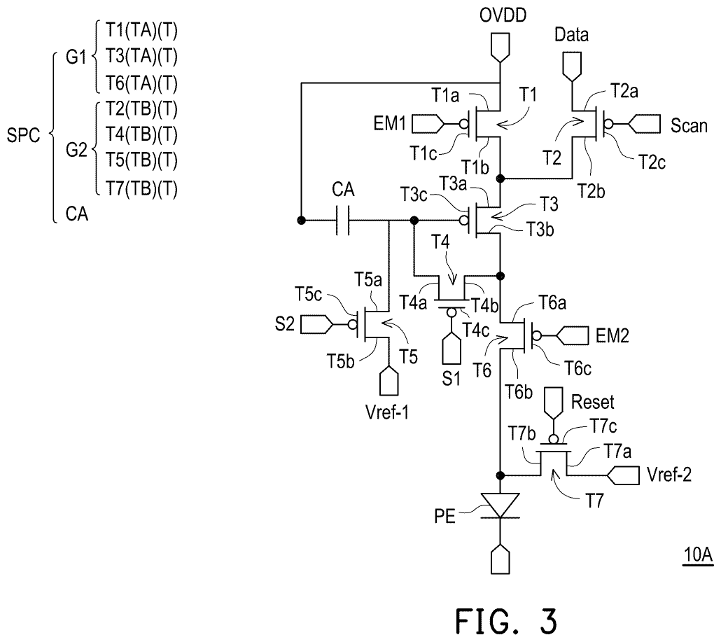

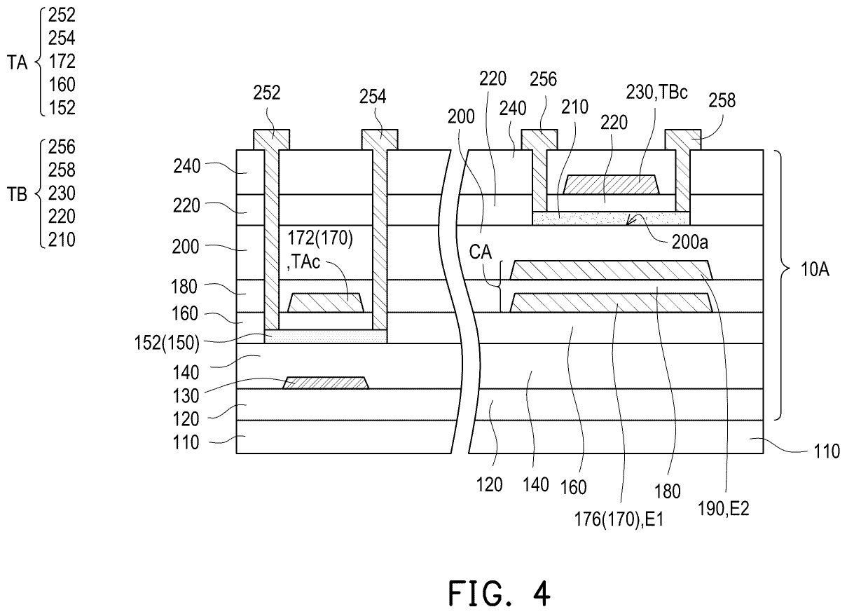

FIG. 3 is a schematic diagram of an equivalent circuit of a pixel structure 10A according to another embodiment of the present disclosure. FIG. 4 is a cross-sectional schematic diagram of a pixel structure 10A according to an embodiment of the present disclosure. The pixel structure 10A in FIG. 3 and FIG. 4 is similar to the pixel structure 10 in FIG. 1 and FIG. 2, and the difference between them lies in that the configuration of the conductive structure CA of the pixel structure 10A in FIG. 3 and FIG. 4 is different from the configuration of the conductive structure C of the pixel structure 10 in FIG. 1 and FIG. 2.

Referring to FIG. 4, specifically, in this embodiment, the pixel structure 10A further includes a third conductive layer 190. The second dielectric layer 180 and the third conductive layer 190 are disposed on the substrate 110. The second dielectric layer 180 covers the first thin film transistor TA and one of the plurality of electrodes E1, E2 of the conductive structure CA (for example: electrode E1). One of the plurality of electrodes E1, E2 of the conductive structure CA (for example: electrode E1) includes a portion 176 of the first conductive layer 170. Another one of the plurality of electrodes E1, E2 of the conductive structure CA (for example: electrode E2) includes the third conductive layer 190. The second dielectric layer 180 is sandwiched between the plurality of electrodes E1, E2 of the conductive structure CA. In some embodiments, the electrodes E1, E2 may selectively belong to two metal layers respectively, wherein the vertical projection area of the electrode E1 belonging to one metal layer on the substrate 110 is larger than the vertical projection area of the second silicon-containing semiconductor layer 210 on the substrate 110, and the vertical projection area of the electrode E2 belonging to another metal layer on the substrate 110 is also larger than the vertical projection area of the second silicon-containing semiconductor layer 210 on the substrate 110.

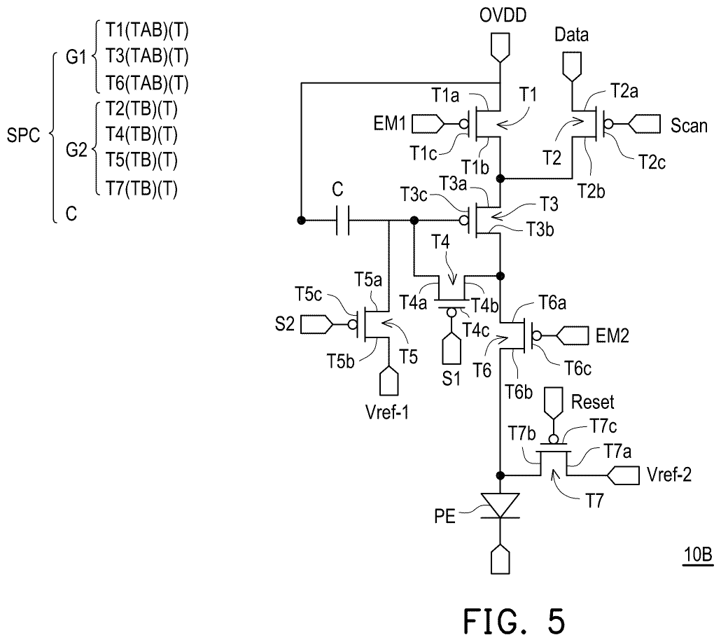

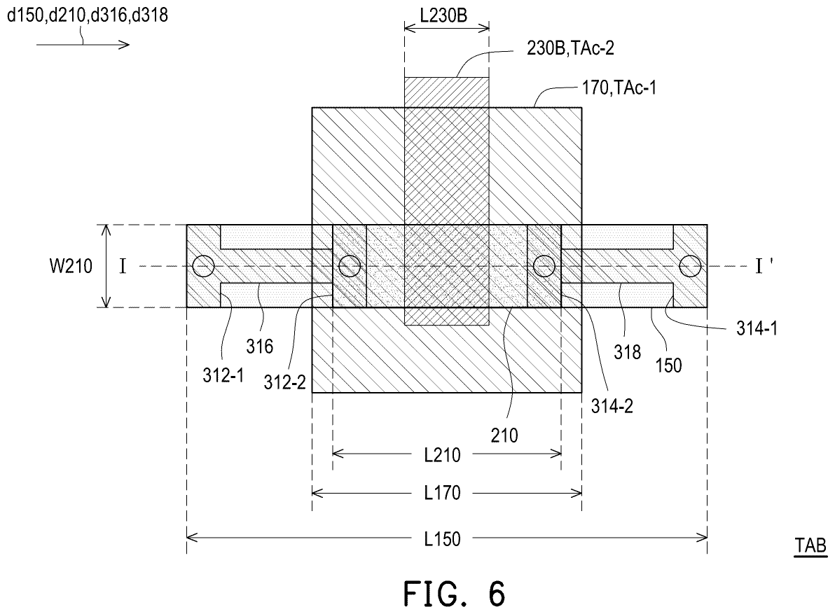

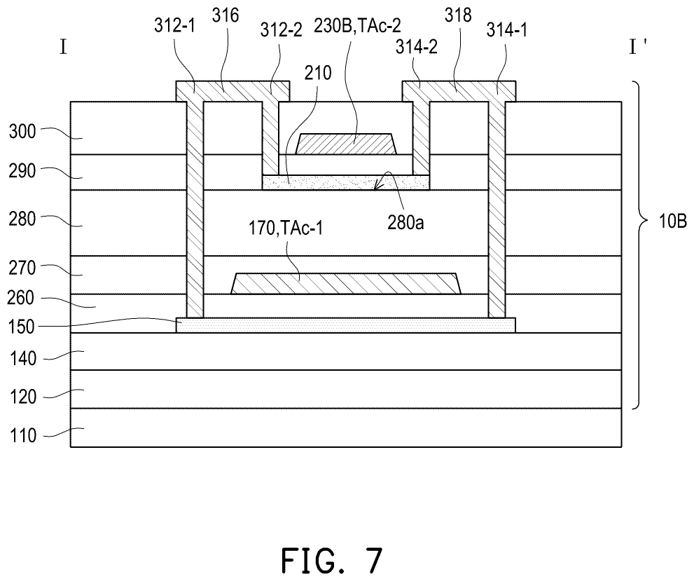

FIG. 5 is a schematic diagram of an equivalent circuit of a pixel structure 10B according to yet another embodiment of the present disclosure. FIG. 6 is a top view and perspective schematic diagram of a first thin film transistor TAB of a pixel structure 10B according to yet another embodiment of the present disclosure. FIG. 7 is a cross-sectional schematic diagram of a first thin film transistor TAB of a pixel structure 10B according to yet another embodiment of the present disclosure. FIG. 7 corresponds to the cross-section line I-I′ of FIG. 6.

Referring to FIG. 5, FIG. 6 and FIG. 7, the pixel structure 10B is disposed on the substrate 110. The pixel structure 10B includes a first control component group G1, a second control component group G2, a first dielectric layer 260, a second dielectric layer 280, a third dielectric layer 290, two junction segments 316, 318 and a pixel element PE, wherein the pixel element PE is electrically connected to the first control component group G1 and the second control component group G2.

The first control component group G1 includes at least one first thin film transistor TAB. In some embodiments, the first thin film transistor TAB has a higher current flow. The first control component group G1 including the first thin film transistor TAB may be called a high current control component group. In some embodiments, the first thin film transistor TAB of the first control component group G1 may include a driving device or a light emitting control device. In some embodiments, the first thin film transistor TAB is electrically connected to the pixel element PE, and the first thin film transistor TAB electrically connected to the pixel element PE may be called a driving device, a light emitting control device or other devices. Taking the 7T1C architecture as an example, the first thin film transistor TAB may be a thin film transistor T1 (i.e., a light emitting control device), a thin film transistor T3 (i.e., a driving device) or a thin film transistor T6 (i.e., a light emitting control device), but the present disclosure is not limited thereto.

Referring to FIG. 6 and FIG. 7, the first thin film transistor TAB has a first silicon-containing semiconductor layer 150, a second silicon-containing semiconductor layer 210, a first conductive layer 170, a second conductive layer 230B, a first source 312-1, a first drain 314-1, a second source 312-2 and a second drain 314-2. The first conductive layer 170 is disposed on the first silicon-containing semiconductor layer 150. The first conductive layer 170 includes a first gate TAc-1. The first dielectric layer 260 covers the first silicon-containing semiconductor layer 150 and is sandwiched between the first conductive layer 170 and the first silicon-containing semiconductor layer 150. The second dielectric layer 280 is disposed and covers the first conductive layer 170, the first silicon-containing semiconductor layer 150 and the first dielectric layer 260. The second silicon-containing semiconductor layer 210 is disposed on the second dielectric layer 280. The second conductive layer 230B is disposed on the second silicon-containing semiconductor layer 210. The second conductive layer 230 includes a second gate TAc-2. The first gate TAc-1 and the second gate TAc-2 may have the same potential. The third dielectric layer 290 covers the second silicon-containing semiconductor layer 210 and is sandwiched between the second conductive layer 230B and the second silicon-containing semiconductor layer 210. The first source 312-1 and the second source 312-2 respectively pass through at least one of the first dielectric layer 260, the second dielectric layer 280 and the third dielectric layer 290 and are connected to each other via the junction segment 316. The first drain 314-1 and the second drain 314-2 respectively pass through at least one of the first dielectric layer 260, the second dielectric layer 280 and the third dielectric layer 290 and are connected to each other via the junction segment 318.

The first thin film transistor TAB is formed by connecting in series one thin film transistor including the first silicon-containing semiconductor layer 150, the first gate TAc-1, the first source 312-1 and the first drain 314-1 with another thin film transistor including the second silicon-containing semiconductor layer 210, the second gate TAc-2, the second source 312-2 and the second drain 314-2. Therefore, the first thin film transistor TAB may satisfy the demand for high current.

In some embodiments, the pixel structure 10B further includes a fourth dielectric layer 300, disposed on the substrate 110 and covering the third dielectric layer 290 and the second conductive layer 230B. The first source 312-1 is disposed on the fourth dielectric layer 300. The first source 312-1 extends through the fourth dielectric layer 300, the third dielectric layer 290, the second dielectric layer 280 and the first dielectric layer 260 to connect to the first silicon-containing semiconductor layer 150. The second source 312-2 is disposed on the fourth dielectric layer 300. The second source 312-2 extends through the fourth dielectric layer 300 and the third dielectric layer 290 to connect to the second silicon-containing semiconductor layer 210. The first source 312-1 and the second source 312-2 are connected to each other via a junction segment 316 disposed on the fourth dielectric layer 300. The first drain 314-1 is disposed on the fourth dielectric layer 300. The first drain 314-1 extends through the fourth dielectric layer 300, the third dielectric layer 290, the second dielectric layer 280 and the first dielectric layer 260 to connect to the first silicon-containing semiconductor layer 150. The second drain 314-2 is disposed on the fourth dielectric layer 300. The second drain 314-2 extends through the fourth dielectric layer 300 and the third dielectric layer 290 to connect to the second silicon-containing semiconductor layer 210. The first drain 314-1 and the second drain 314-2 are connected to each other via a junction segment 318 disposed on the fourth dielectric layer 300.

In some embodiments, the pixel structure 10B further includes a dielectric layer 270, disposed on the substrate 110. The dielectric layer 270 is disposed and covers the first conductive layer 170, the first silicon-containing semiconductor layer 150 and the first dielectric layer 260 and is sandwiched between the second dielectric layer 280 and the first conductive layer 170. In some embodiments, any one of the first dielectric layer 260, the second dielectric layer 280, the third dielectric layer 290, the fourth dielectric layer 300 and the dielectric layer 270 may be a single layer or multilayer structure. In some embodiments, the material of any one of the first dielectric layer 260, the second dielectric layer 280, the third dielectric layer 290, the fourth dielectric layer 300 and the dielectric layer 270 may be inorganic material (for example: silicon oxide, silicon nitride, silicon oxynitride, or a stacked layer of at least two of the above materials), organic material or a combination thereof. In some embodiments, if any one of the first dielectric layer 260, the second dielectric layer 280, the third dielectric layer 290, the fourth dielectric layer 300 and the dielectric layer 270 is a multilayer structure, the materials of the multiple film layers of the multilayer structure may be the same or different. In some embodiments, any two of the first dielectric layer 260, the second dielectric layer 280, the third dielectric layer 290, the fourth dielectric layer 300 and the dielectric layer 270 may use the same or different materials.

It is worth noting that the vertical projection area of the second silicon-containing semiconductor layer 210 on the substrate 110 is smaller than or substantially equal to the vertical projection area of the first conductive layer 170 on the substrate 110. The vertical projection area of the second silicon-containing semiconductor layer 210 on the substrate 110 is located within the vertical projection area of the first conductive layer 170 on the substrate 110. Thereby, the second silicon-containing semiconductor layer 210 may be formed on the flat surface 280a of the second dielectric layer 280, and disconnection problems are not likely to occur.

Referring to FIG. 6, in some embodiments, the length L150 of the first silicon-containing semiconductor layer 150 may be greater than the length L170 of the first conductive layer 170 and the length L210 or width W210 of the second silicon-containing semiconductor layer 210, and the length L170 of the first conductive layer 170 is greater than or substantially equal to the length L210 or width W210 of the second silicon-containing semiconductor layer 210. In some embodiments, the length L230B of the second conductive layer 230B may be the smallest, and the length L150 of the first silicon-containing semiconductor layer 150 may be the largest. In some embodiments, the length L210 of the second silicon-containing semiconductor layer 210 may be greater than the length L230B of the second conductive layer 230B and smaller than or equal to the length L150 of the first silicon-containing semiconductor layer 150.

Referring to FIG. 6, in some embodiments, the extending direction d150 of the first silicon-containing semiconductor layer 150 and the extending direction d210 of the second silicon-containing semiconductor layer 210 are substantially parallel, and the extending direction d316/d138 of any one of the plurality of junction segments 316, 318 is substantially parallel to one of the extending direction d150 of the first silicon-containing semiconductor layer 150 and the extending direction d210 of the second silicon-containing semiconductor layer 210, but the present disclosure is not limited thereto. In some embodiments, if the extending direction d150 of the first silicon-containing semiconductor layer 150 and the extending direction d210 of the second silicon-containing semiconductor layer 210 are parallel, the second conductive layer 230B may be selectively substantially perpendicular to the extending direction d150 of the first silicon-containing semiconductor layer 150 and the extending direction d210 of the second silicon-containing semiconductor layer 210, but the present disclosure is not limited thereto.

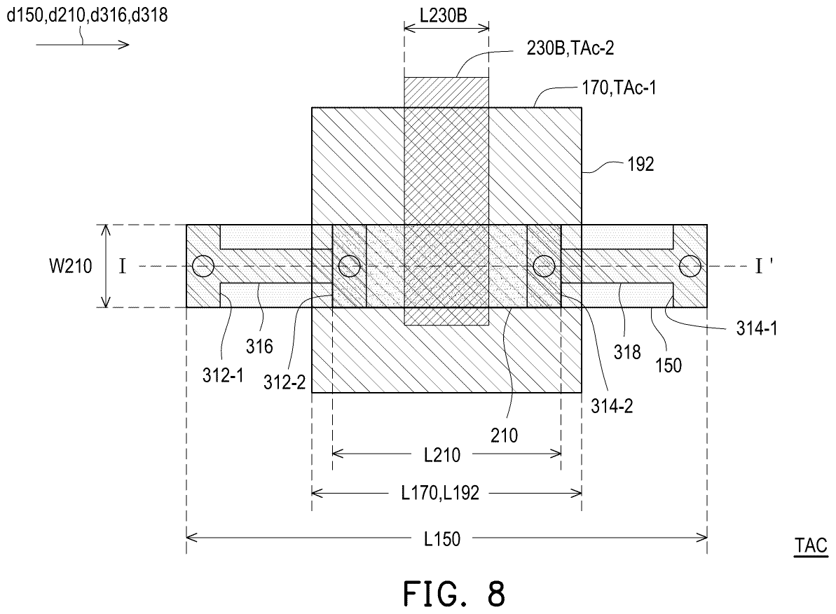

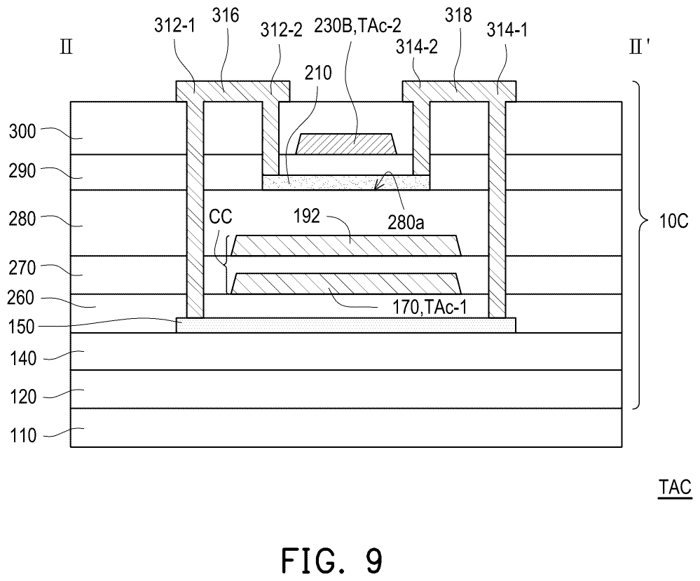

FIG. 8 is a top view and perspective view of the first thin film transistor TAC of the pixel structure 10C according to another embodiment of the present disclosure. FIG. 9 is a cross-sectional view of the first thin film transistor TAC of the pixel structure 10C according to another embodiment of the present disclosure. FIG. 8 corresponds to the cross-section line II-II′ of FIG. 7.

The pixel structure 10C and its first thin film transistor TAC in FIG. 8 and FIG. 9 are similar to the pixel structure 10C and its first thin film transistor TAB in FIG. 6 and FIG. 7, and the difference between them is that: in the embodiments of FIG. 8 and FIG. 9, the pixel structure 10C further includes a third conductive layer 192. Referring to FIG. 8 and FIG. 9, the third conductive layer 192 is disposed on the dielectric layer 270 and corresponds to the first conductive layer 170. The third conductive layer 192 is sandwiched between the second dielectric layer 280 and the dielectric layer 270. The third conductive layer 192 corresponds to the first conductive layer 170 to form a conductive structure CC.

Referring to FIG. 8, in some embodiments, the length L150 of the first silicon-containing semiconductor layer 150 is greater than the length L170/L192 of any one of the first conductive layer 170 and the third conductive layer 192 and the length L210 or width W210 of the second silicon-containing semiconductor layer 210, and the length L170/L192 of any one of the first conductive layer 170 and the third conductive layer 192 is greater than or substantially equal to the length L210 or width W210 of the second silicon-containing semiconductor layer 210.

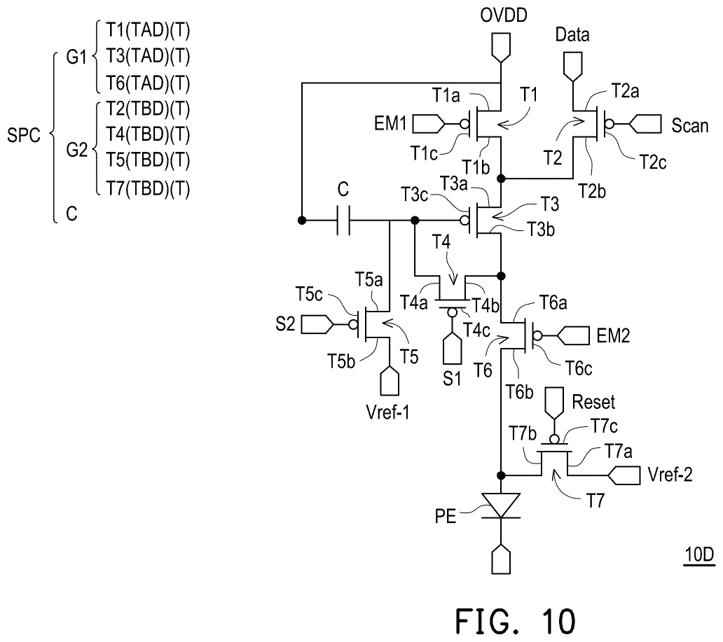

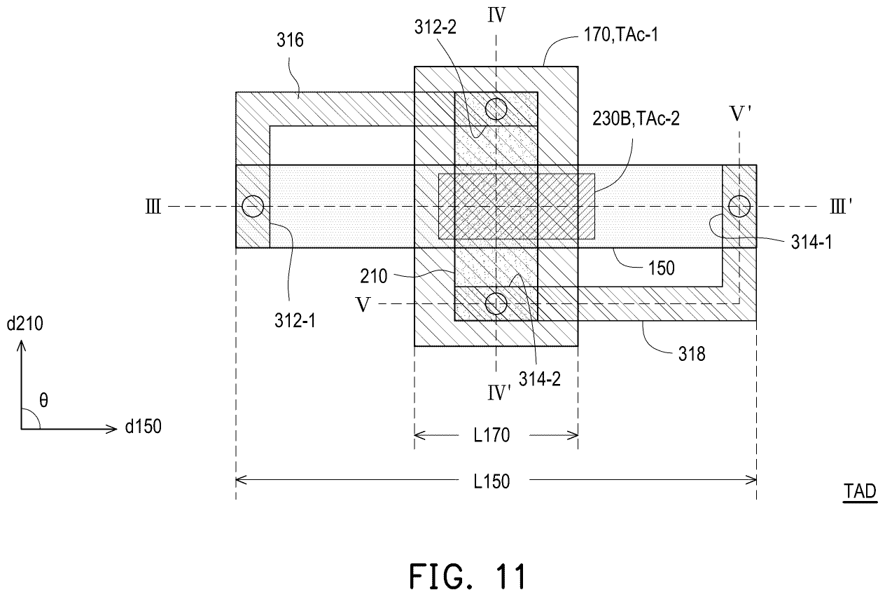

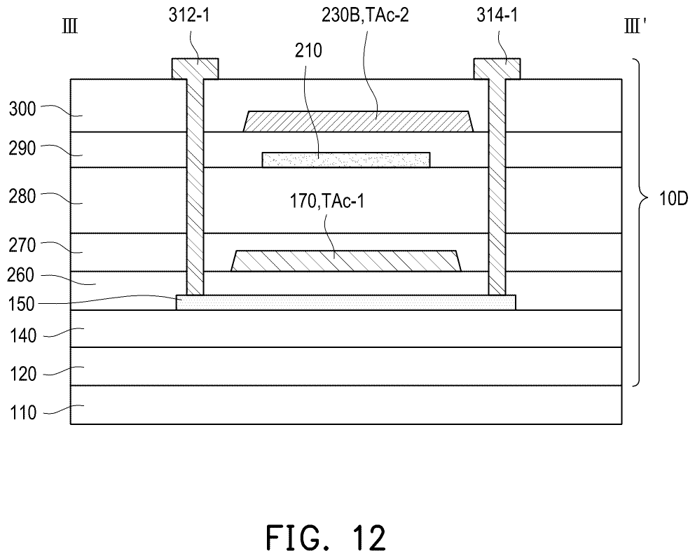

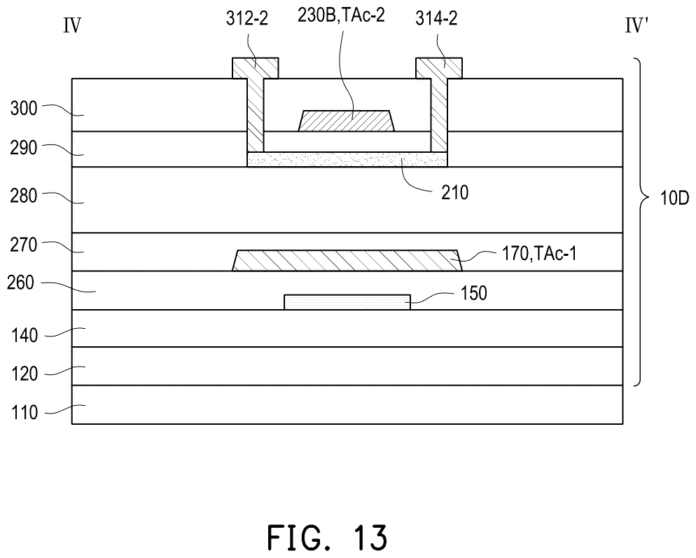

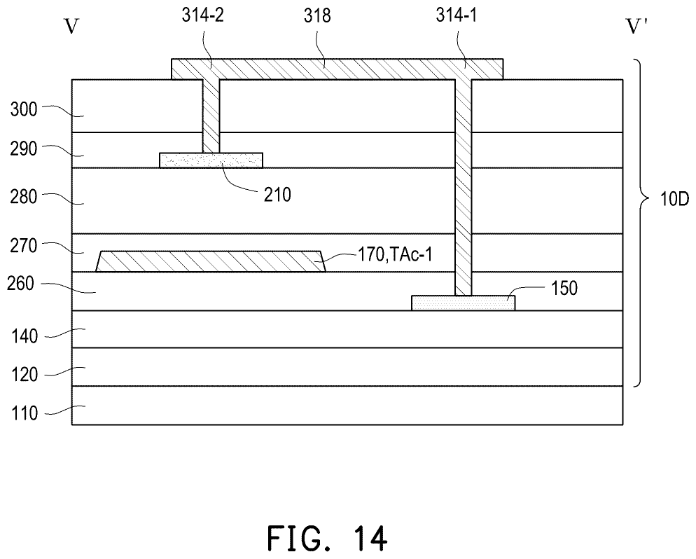

FIG. 10 is an equivalent circuit diagram of the pixel structure 10D according to still another embodiment of the present disclosure. FIG. 11 is a top view and perspective view of the first thin film transistor TAD of the pixel structure 10D according to still another embodiment of the present disclosure. FIG. 12 is a cross-sectional view of the first thin film transistor TAD of the pixel structure 10D according to still another embodiment of the present disclosure. FIG. 12 corresponds to the cross-section line III-III′ of FIG. 11. FIG. 13 is a cross-sectional view of the first thin film transistor TAD of the pixel structure 10D according to still another embodiment of the present disclosure. FIG. 13 corresponds to the cross-section line IV-IV′ of FIG. 11. FIG. 14 is a cross-sectional view of the first thin film transistor TAD of the pixel structure 10D according to still another embodiment of the present disclosure. FIG. 14 corresponds to the cross-section line V-V′ of FIG. 11.

The pixel structure 10D and its first thin film transistor TAD in FIG. 10, FIG. 11, FIG. 12, FIG. 13 and FIG. 14 are similar to the pixel structure 10B and its first thin film transistor TAB in FIG. 5, FIG. 6 and FIG. 7, and the difference between them is that: the structures of the first thin film transistors TAB and TAD are different.

Referring to FIG. 10, FIG. 11, FIG. 12, FIG. 13 and FIG. 14, specifically, in this embodiment, the extending direction d150 of the first silicon-containing semiconductor layer 150 (labeled in FIG. 11) and the extending direction d210 of the second silicon-containing semiconductor layer 210 (labeled in FIG. 11) are substantially intersected. In this embodiment, the angle between the extending direction d150 of the first silicon-containing semiconductor layer 150 and the extending direction d210 of the second silicon-containing semiconductor layer 210 is θ, and 0°<θ≤90°. In the case where the extending direction d150 of the first silicon-containing semiconductor layer 150 and the extending direction d210 of the second silicon-containing semiconductor layer 210 are intersected, the shapes of the junction segments 316, 318 may have various implementations. For example, in this embodiment, the shapes of the junction segments 316, 318 may be bent/curved or other shapes.

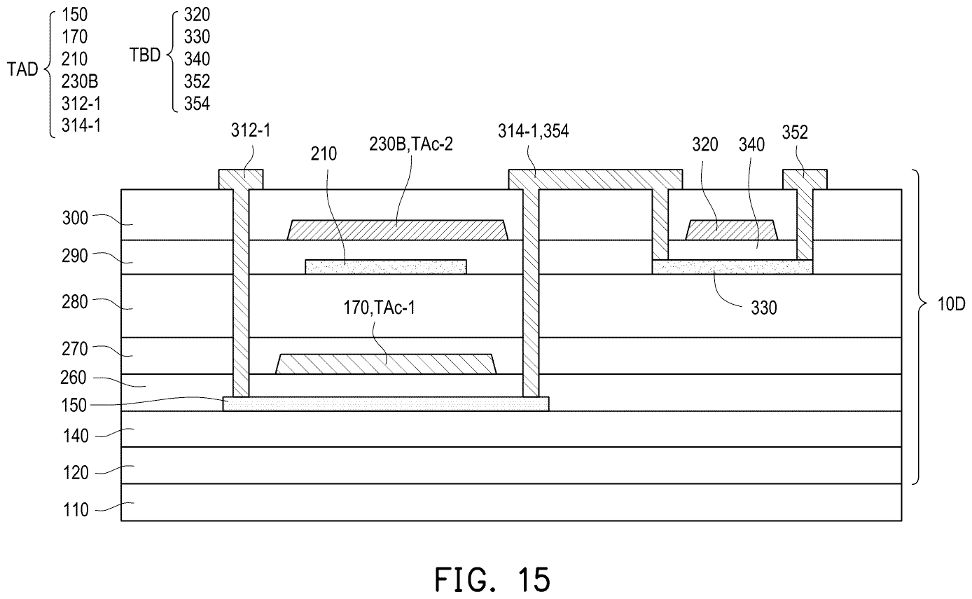

FIG. 15 is a cross-sectional view of the first thin film transistor TAD and the second thin film transistor TB of the pixel structure 10D according to still another embodiment of the present disclosure. Referring to FIG. 10 and FIG. 15, the second control component group G2 of the pixel structure 10D includes at least one second thin film transistor TBD. In this embodiment, the second thin film transistor TBD has a conductive layer 320, a silicon-containing semiconductor layer 330 corresponding to the conductive layer 320, a gate insulating layer 340 sandwiched between the conductive layer 320 and the silicon-containing semiconductor layer 330, a source 352 connected to the silicon-containing semiconductor layer 330, and a drain 354 connected to the silicon-containing semiconductor layer 330.

In this embodiment, the conductive layer 320 of the second thin film transistor TBD and one of the first conductive layer 170 and the second conductive layer 230B belong to the same film layer. For example, in this embodiment, the conductive layer 320 of the second thin film transistor TBD may belong to the same film layer as the second conductive layer 230B, but the present disclosure is not limited thereto.

In this embodiment, the gate insulating layer 340 of the second thin film transistor TBD may belong to the same film layer as one of the first dielectric layer 260, the second dielectric layer 280, and the third dielectric layer 290. For example, in this embodiment, the gate insulating layer 340 of the second thin film transistor TBD may belong to the same film layer as the third dielectric layer 290, but the present disclosure is not limited thereto.

In this embodiment, the silicon-containing semiconductor layer 330 of the second thin film transistor TBD may belong to the same film layer as one of the first silicon-containing semiconductor layer 150 and the second silicon-containing semiconductor layer 210. For example, in this embodiment, the silicon-containing semiconductor layer 330 of the second thin film transistor TBD may belong to the same film layer as the second silicon-containing semiconductor layer 210, but the present disclosure is not limited thereto.

Referring to FIG. 11 and FIG. 15, in this embodiment, the source 352 of the second thin film transistor TBD may include one of the first source 312-1 and the second source 312-2 of the first thin film transistor TAD, or the drain 354 of the second thin film transistor TBD may include one of the first drain 314-1 and the second drain 314-2 of the first thin film transistor TAD. For example, in this embodiment, the drain 354 of the second thin film transistor TBD may include the first drain 314-1 of the first thin film transistor TAD, but the present disclosure is not limited thereto.

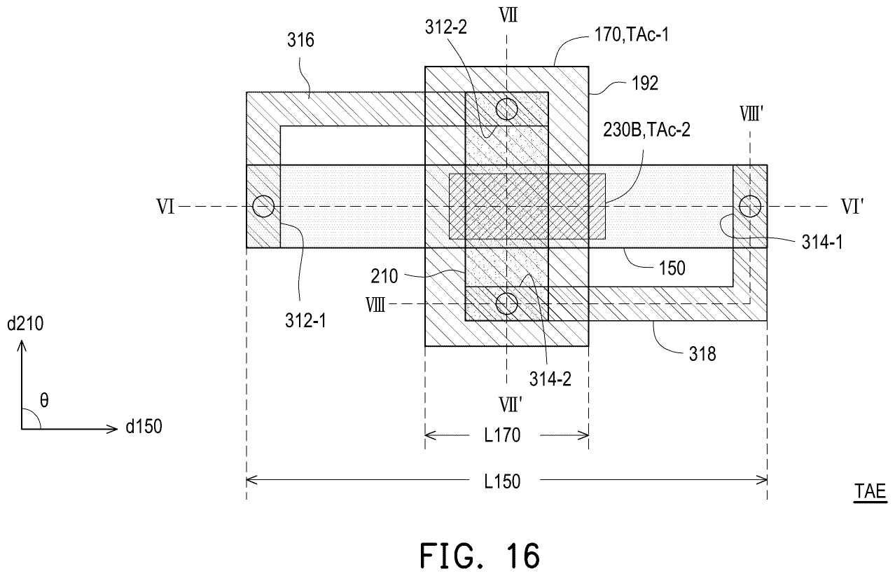

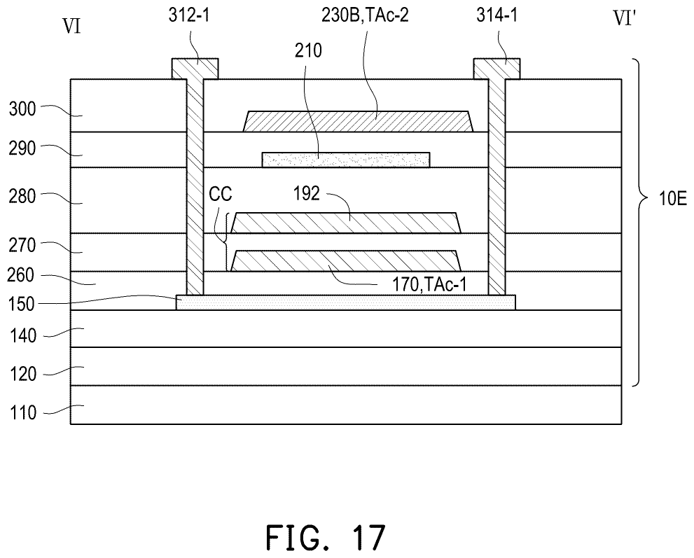

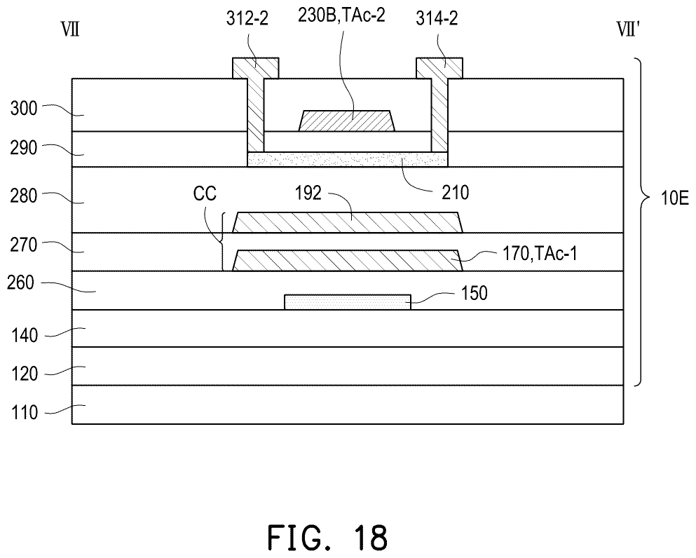

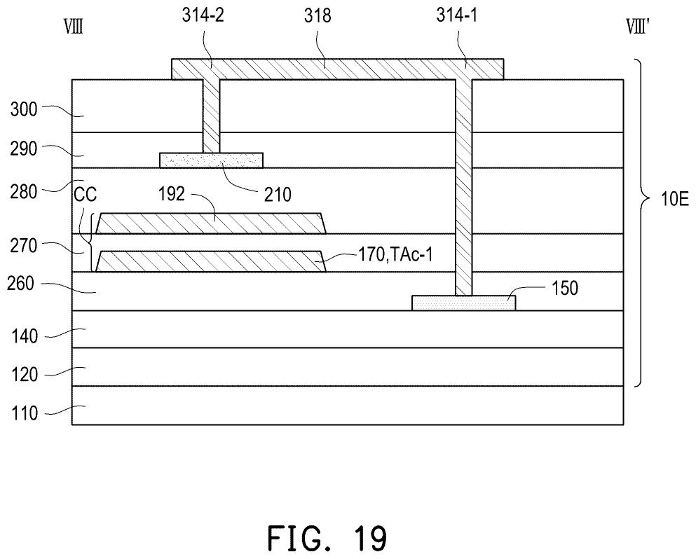

FIG. 16 is a top view and perspective view of the first thin film transistor TAE of the pixel structure 10E according to an embodiment of the present disclosure. FIG. 17 is a cross-sectional view of the first thin film transistor TAE of the pixel structure 10E according to an embodiment of the present disclosure. FIG. 17 corresponds to the cross-section line VI-VI′ of FIG. 16. FIG. 18 is a cross-sectional view of the first thin film transistor TAE of the pixel structure 10E according to another embodiment of the present disclosure. FIG. 18 corresponds to the cross-section line VII-VII′ of FIG. 16. FIG. 19 is a cross-sectional view of the first thin film transistor TAE of the pixel structure 10E according to another embodiment of the present disclosure. FIG. 19 corresponds to the cross-section line VIII-VIII′ of FIG. 16.

The pixel structure 10E and its first thin film transistor TAE in FIG. 16, FIG. 17, FIG. 18, and FIG. 19 are similar to the pixel structure 10C and its first thin film transistor TAC in FIG. 8 and FIG. 9, and the difference between them lies in: the structures of the first thin film transistors TAC and TAE are different.

Referring to FIG. 16, FIG. 17, FIG. 18, and FIG. 19, specifically, in this embodiment, the extending direction d150 of the first silicon-containing semiconductor layer 150 and the extending direction d210 of the second silicon-containing semiconductor layer 210 are substantially intersected. In this embodiment, the angle between the extending direction d150 of the first silicon-containing semiconductor layer 150 and the extending direction d210 of the second silicon-containing semiconductor layer 210 is θ, and 0°, and 0 ≤90°. In the case where the extending direction d150 of the first silicon-containing semiconductor layer 150 and the extending direction d210 of the second silicon-containing semiconductor layer 210 are intersected, the shapes of the junction segments 316, 318 may have various implementations. For example, in this embodiment, the shapes of the junction segments 316, 318 may be bent/curved or other shapes.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A pixel structure disposed on a substrate, the pixel structure comprising:
a first control component group, a second control component group, a conductive structure, a first dielectric layer, and a pixel element, wherein the pixel element is electrically connected to the conductive structure, the first control component group, and the second control component group;
the first control component group comprising at least one first thin film transistor, wherein the first thin film transistor has a portion of a first silicon-containing semiconductor layer, a portion of a first conductive layer corresponding to the portion of the first silicon-containing semiconductor layer, a first gate dielectric layer disposed between the first silicon-containing semiconductor layer and the first conductive layer, a first source connected to the portion of the first silicon-containing semiconductor layer, and a first drain connected to the portion of the first silicon-containing semiconductor layer, and the portion of the first conductive layer comprises a first gate;
the first dielectric layer disposed on and covering the substrate, the first control component group, and the conductive structure;
the second control component group comprising at least one second thin film transistor, wherein the second thin film transistor has a second silicon-containing semiconductor layer, a second conductive layer disposed on the second silicon-containing semiconductor layer, a second gate dielectric layer disposed between the second silicon-containing semiconductor layer and the second conductive layer, a second source connected to the second silicon-containing semiconductor layer, and a second drain connected to the second silicon-containing semiconductor layer, the second conductive layer comprises a second gate, the second thin film transistor is located on the conductive structure, and a vertical projection area of at least a portion of the conductive structure on the substrate is greater than or substantially equal to a vertical projection area of the second silicon-containing semiconductor layer on the substrate.

2. The pixel structure as claimed in claim 1, wherein the conductive structure is a capacitor structure, and a vertical projection of at least one of electrodes of the capacitor structure on the substrate is greater than or substantially equal to the vertical projection area of the second silicon-containing semiconductor layer on the substrate.

3. The pixel structure as claimed in claim 2, wherein one of the electrodes of the conductive structure comprises a portion of the first silicon-containing semiconductor layer, and another one of the electrodes of the conductive structure comprises a portion of the first conductive layer.

4. The pixel structure as claimed in claim 2, wherein one of the electrodes of the conductive structure comprises a portion of the first silicon-containing semiconductor layer, another one of the electrodes of the conductive structure comprises a portion of the first conductive layer, the first gate dielectric layer covers the one of the electrodes of the conductive structure, and the first gate dielectric layer is sandwiched between the electrodes of the conductive structure.

5. The pixel structure as claimed in claim 2, further comprising:
a second dielectric layer and a third conductive layer disposed on the substrate, wherein the second dielectric layer covers the at least one first thin film transistor and one of the electrodes of the conductive structure, the one of the electrodes of the conductive structure comprises a portion of the first conductive layer, another one of the electrodes of the conductive structure comprises the third conductive layer, and the second dielectric layer is sandwiched between the electrodes of the conductive structure.

6. The pixel structure as claimed in claim 2, wherein the first thin film transistor of the first control component group comprises a driving device or a light emitting control device.

7. The pixel structure as claimed in claim 2, further comprising:
a conductive layer and a buffer layer disposed on the substrate, wherein the conductive layer is located below the portion of the first silicon-containing semiconductor layer of the at least one first thin film transistor, the first conductive layer is located above the portion of the first silicon-containing semiconductor layer of the at least one first thin film transistor, and the buffer layer is sandwiched between the portion of the first silicon-containing semiconductor layer and the conductive layer.

8. The pixel structure as claimed in claim 2, further comprising:
a dielectric layer disposed on the substrate and covering the first control component group, the second control component group and the conductive structure, wherein the first source and the first drain of the first thin film transistor penetrate through the dielectric layer, the first dielectric layer and the first gate dielectric layer and connect to the portion of the first silicon-containing semiconductor layer, and the second source and the second drain of the second thin film transistor penetrate through the dielectric layer and the second gate dielectric layer and connect to the second silicon-containing semiconductor layer.

9. The pixel structure as claimed in claim 2, wherein the second gate of the second thin film transistor of the second control component group is electrically connected to a scan line, the second source of the second thin film transistor of the second control component group is electrically connected to a data line, the second drain of the second thin film transistor of the second control component group is electrically connected to the first thin film transistor of the first control component group, and the first drain of the first thin film transistor of the first control component group is electrically connected to the pixel element.

10. A pixel structure disposed on a substrate, the pixel structure comprising:
a first control component group, a second control component group, a first dielectric layer, a second dielectric layer, a third dielectric layer, two junction segments and a pixel element, wherein the pixel element is electrically connected to the first control component group and the second control component group;
the first control component group comprises at least one first thin film transistor, wherein the first thin film transistor has a first silicon-containing semiconductor layer, a second silicon-containing semiconductor layer, a first conductive layer, a second conductive layer, a first source, a first drain, a second source and a second drain, the first conductive layer is located on the first silicon-containing semiconductor layer, the first dielectric layer covers the first silicon-containing semiconductor layer and is sandwiched between the first conductive layer and the first silicon-containing semiconductor layer, the second dielectric layer is disposed and covers the first conductive layer, the first silicon-containing semiconductor layer and the first dielectric layer, the second silicon-containing semiconductor layer is disposed on the second dielectric layer, the second conductive layer is disposed on the second silicon-containing semiconductor layer, the third dielectric layer covers the second silicon-containing semiconductor layer and is sandwiched between the second conductive layer and the second silicon-containing semiconductor layer, the first source and the second source respectively penetrate through at least one of the first dielectric layer, the second dielectric layer and the third dielectric layer and are connected to each other via one of the junction segments, the first drain and the second drain respectively penetrate through at least one of the first dielectric layer, the second dielectric layer and the third dielectric layer and are connected to each other via another one of the junction segments;
a vertical projection area of the second silicon-containing semiconductor layer on the substrate is smaller than or substantially equal to a vertical projection area of the first conductive layer on the substrate, the first conductive layer comprises a first gate, and the second conductive layer comprises a second gate.

11. The pixel structure as claimed in claim 10, wherein a length of the first silicon-containing semiconductor layer is greater than a length of the first conductive layer and a length or a width of the second silicon-containing semiconductor layer, and the length of the first conductive layer is greater than or substantially equal to the length or the width of the second silicon-containing semiconductor layer.

12. The pixel structure as claimed in claim 10, wherein an extending direction of the first silicon-containing semiconductor layer is substantially parallel to an extending direction of the second silicon-containing semiconductor layer, and an extending direction of any one of the junction segments is substantially parallel to one of the extending direction of the first silicon-containing semiconductor layer and the extending direction of the second silicon-containing semiconductor layer.

13. The pixel structure as claimed in claim 10, wherein an extending direction of the first silicon-containing semiconductor layer substantially intersects with an extending direction of the second silicon-containing semiconductor layer.

14. The pixel structure as claimed in claim 10, further comprising:
a fourth dielectric layer disposed on the substrate and covering the third dielectric layer and the second conductive layer, wherein the first source penetrates through the first dielectric layer, the second dielectric layer, the third dielectric layer, and the fourth dielectric layer to connect to the first silicon-containing semiconductor layer, the second source penetrates through the third dielectric layer and the fourth dielectric layer to connect to the second silicon-containing semiconductor layer, the first drain penetrates through the first dielectric layer, the second dielectric layer, the third dielectric layer, and the fourth dielectric layer to connect to the first silicon-containing semiconductor layer, and the second drain penetrates through the third dielectric layer and the fourth dielectric layer to connect to the second silicon-containing semiconductor layer.

15. The pixel structure as claimed in claim 10, further comprising:
a third conductive layer and a dielectric layer disposed on the substrate, wherein the dielectric layer is disposed and covers the first conductive layer, the first silicon-containing semiconductor layer, and the first dielectric layer and is sandwiched between the second dielectric layer and the first conductive layer, the third conductive layer is disposed on the dielectric layer and corresponds to the first conductive layer.

16. The pixel structure as claimed in claim 15, wherein the third conductive layer corresponds to the first conductive layer to constitute a conductive structure.

17. The pixel structure as claimed in claim 15, wherein a length of the first silicon-containing semiconductor layer is greater than a length of any one of the first conductive layer and the third conductive layer and a length or a width of the second silicon-containing semiconductor layer, and the length of any one of the first conductive layer and the third conductive layer is greater than or substantially equal to a length or a width of the second silicon-containing semiconductor layer.

18. The pixel structure as claimed in claim 15, wherein an extending direction of the first silicon-containing semiconductor layer is substantially parallel to an extending direction of the second silicon-containing semiconductor layer, and an extending direction of any one of the junction segments is substantially parallel to one of the extending direction of the first silicon-containing semiconductor layer and the extending direction of the second silicon-containing semiconductor layer.

19. The pixel structure as claimed in claim 15, wherein an extending direction of the first silicon-containing semiconductor layer substantially intersects with an extending direction of the second silicon-containing semiconductor layer.

20. The pixel structure as claimed in claim 10, wherein the second control component group comprises at least one second thin film transistor, the second thin film transistor having a conductive layer, a silicon-containing semiconductor layer corresponding to the conductive layer, a gate insulating layer sandwiched between the conductive layer and the silicon-containing semiconductor layer, a source connected to the silicon-containing semiconductor layer, and a drain connected to the silicon-containing semiconductor layer;
the conductive layer of the second thin film transistor belongs to the same film layer as the first conductive layer and the second conductive layer, the gate insulating layer of the second thin film transistor belongs to the same film layer as one of the first dielectric layer, the second dielectric layer, and the third dielectric layer, the silicon-containing semiconductor layer of the second thin film transistor belongs to the same film layer as one of the first silicon-containing semiconductor layer and the second silicon-containing semiconductor layer;
the source of the second thin film transistor comprises one of the first source and the second source, or the drain of the second thin film transistor comprises one of the first drain and the second drain.

21. The pixel structure as claimed in claim 10, wherein the first thin film transistor of the first control component group comprises a driving element or a light emitting control element.
